(19) United States
(12) Patent Application Publication
(10) Pub. No.: US 2018/0180687 A1
(43) Pub. Date: Jun. 28, 2018

(54) ADJUSTABLE COIL FOR MAGNETIC PARTICLE INSPECTION

(71) Applicant: CATERPILLAR INC., Peoria, IL (US)

(72) Inventors: Christopher Anthony KINNEY, Iuka, MS (US); Dale Clifford GRIGORENKO, Corinth, MS (US); Dan John PIERCE, Deedwood, SD (US)

(73) Assignee: CATERPILLAR INC., PEORIA, IL (US)

(21) Appl. No.: 15/389,767

(22) Filed: Dec. 23, 2016

(51) Int. Cl. G01R 33/12; G01R 33/00

(52) U.S. Cl. CPC G01R 33/1276; G01R 33/0052

(57) ABSTRACT

An adjustable electric coil for magnetic particle inspection has a plurality of telescopically interconnected sections. Each of the interconnected sections includes a connector element and a conducting element. The conducting element is joined at a proximal end to an end surface of a peripheral wall of the connector element, and a central opening is defined through the connector element on one side of the conducting element. The conducting element of each section is inserted through the central opening of an adjacent connector element of an adjacent section.

### TECHNICAL FIELD

The present disclosure relates generally to magnetic particle inspection, and more particularly, to an adjustable coil for magnetic particle inspection.

### BACKGROUND

When performing magnetic particle inspection on parts with a variety of different diameters and sizes the best results are obtained if the part being inspected fits as closely as possible to the inside diameter of the magnetized coil used in performing the inspection. The area closest to the inside surface at the inner diameter of the magnetized coil generates the largest magnetic field that is induced into the part positioned inside the coil. Conventional solutions for providing a good fit between a part being inspected and the inner diameter of a magnetized coil are to substitute magnetized coils of different diameters for inspection of parts having different diameters and sizes. Typically, each time a different “specialty” coil of a different diameter is needed for a part of different size, the magnetic particle inspection bench must be disassembled in order to replace the coil. The bed must generally be removed from the test bench, headstock and tailstock must be disassembled, and then the existing coil must be removed before replacement with a new coil of a different size. This process can be time consuming and expensive, and a large variety of different size coils must be stocked in order to be able to perform the magnetic particle inspection on a variety of different size parts.

One method of adjusting a magnetic sensing coil is described in U.S. Pat. No. 4,916,394 (the '394 patent) issued to Thompson on Apr. 10, 1990. The '394 patent describes an adjustable mounting shoe for sensing coils of a pipe magnetic inspection apparatus. The mounting shoe has a base member with a recess in a surface thereof in which magnetic coils are mounted. Adjustable contact members are mounted on opposite sides of the recess and provided with contact surfaces positioned to engage the exterior surface of a pipe while supporting the magnetic sensing coils in an optimum sensing range from the surface of the pipe.

Although the system of the '394 patent purports to support the magnetic sensing coils in an optimum sensing range from the surface of the pipe, the use of a mounting shoe, adjustable contact members, and shims, as required in the '394 patent results in a complex assembly and process for adjusting the position of the magnetic sensing coils at the best location relative to parts of different sizes, and also a lot of easily misplaced or damaged parts.

The disclosed system is directed to overcoming one or more of the problems set forth above.

### SUMMARY

In one aspect, the present disclosure is directed to an adjustable electric coil for magnetic particle inspection. The adjustable electric coil includes multiple telescopically interconnected sections, and each of the interconnected sections includes a connector element and a conducting element. The conducting element is joined at a proximal end to an end surface of a peripheral wall of the connector element, and a central opening is defined through the connector element on one side of the conducting element. The conducting element of each section is inserted through the central opening of an adjacent connector element of an adjacent section.

In another aspect, the present disclosure is directed to a section for an adjustable electric coil used to perform magnetic particle inspection of a component. The section includes a connector element and a conducting element. The conducting element is joined at a proximal end to an end surface of a peripheral wall of the connector element, and a central opening is defined through the connector element on one side of the conducting element. The conducting element of each section is configured to be inserted a greater or lesser distance through an opening in an adjacent connector element of an adjacent section that is configured to be telescopically interconnected with the section.

In yet another aspect, the present disclosure is directed to a method of forming an adjustable electric coil for use with a magnetic particle inspection apparatus. The method includes forming a plurality of sections configured to be telescopically interconnected with each other. Each of the interconnected sections includes a connector element and a conducting element, and the conducting element is joined at a proximal end to an end surface of a peripheral wall of the connector element. A central opening is defined through the connector element on one side of the conducting element. The method includes inserting the conducting element of each section through the central opening of an adjacent connector element of an adjacent section.

### BRIEF DESCRIPTION OF THE DRAWINGS

FIG. 1 is a schematic illustration of an exemplary disclosed adjustable electric coil;

FIG. 2 is a schematic illustration of a portion of the exemplary disclosed adjustable electric coil of FIG. 1;

FIG. 3 is a perspective view of part of the portion of the exemplary disclosed adjustable electric coil of FIG. 2;

FIG. 4 is a perspective view of one section of an exemplary disclosed adjustable electric coil;

FIG. 5 is a perspective view of two sections of an exemplary disclosed adjustable electric coil telescopically interconnected in a contracted position; and

FIG. 6 is a perspective view of the two sections of the exemplary disclosed adjustable electric coil of FIG. 5 telescopically interconnected in an expanded position.

### DETAILED DESCRIPTION

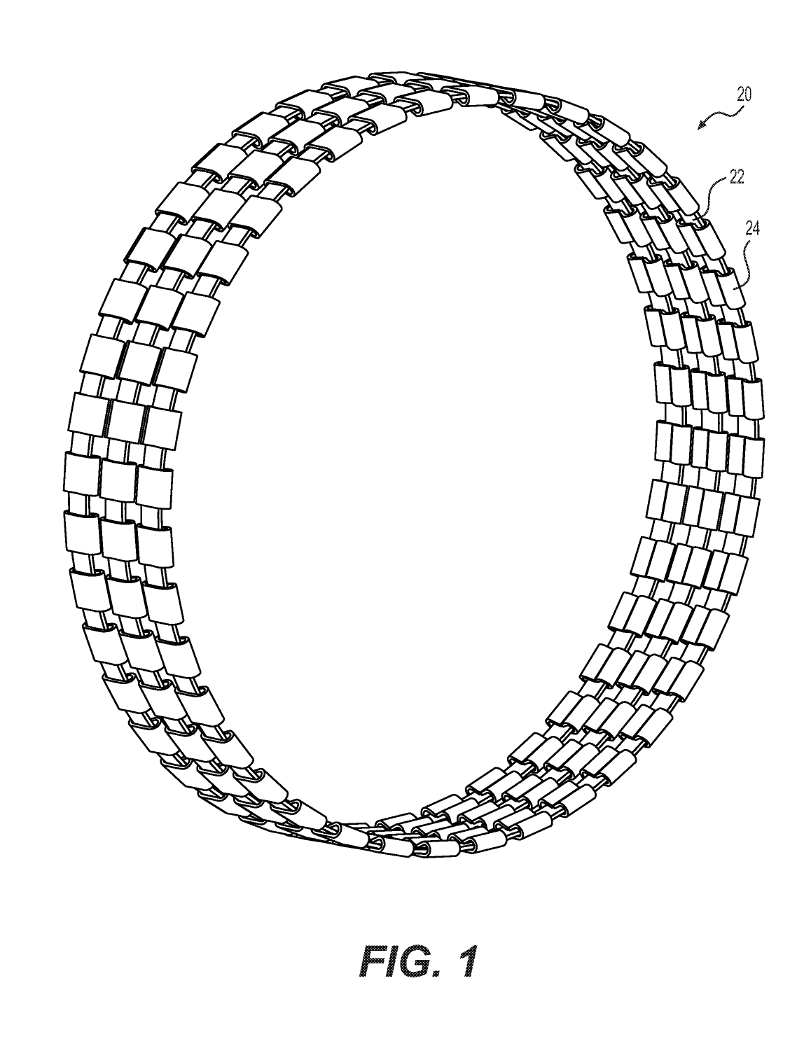

FIG. 1 is a schematic representation of a multi-wrap electric coil 20 according to one exemplary embodiment of this disclosure. Although the representation of FIG. 1 shows three coils, and for the purposes of illustration, the three coils appear to be separate and unconnected coils, an electric coil for magnetic particle inspection according to this disclosure is a single continuous, multi-wrap electric coil, forming a continuous electrical path, which may include 3 total turns or wraps, 5 total turns or wraps, or a different number of turns or wraps. The number of wraps may depend on the specific application and the strength of the magnetic field that is to be generated when a current is sent through the coil.

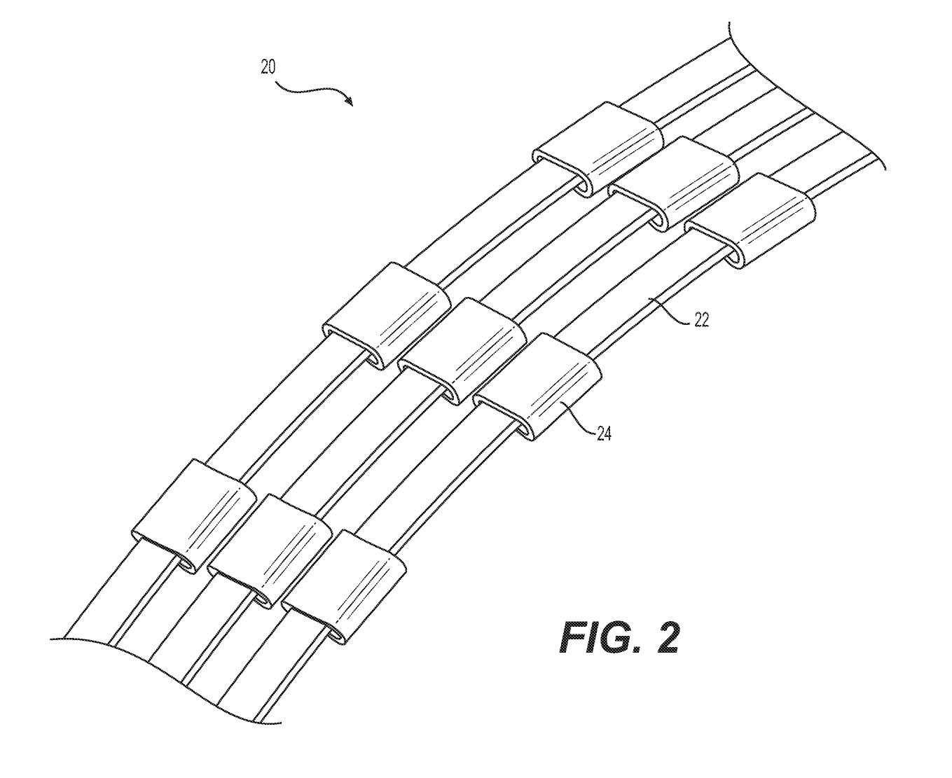

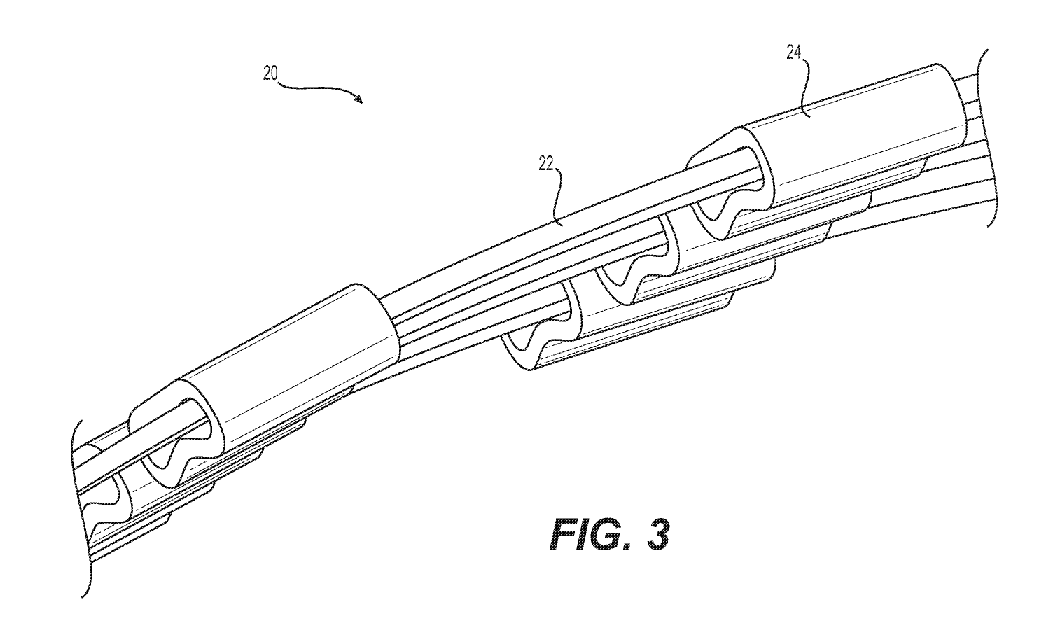

An exemplary 5 wrap electric coil used for magnetic particle inspection may be formed using 4/0 AWG (American Wire Gauge) sized round wire configured to carry high current in the range from approximately 1000-10,000 amps at voltages between 12 volts and 24 volts. The exemplary coil configurations illustrated in FIGS. 1-6 are made up of a plurality of sections 12, each including a plurality of flat conducting elements 22 that may each have a cross-sectional area, resistance to electrical current flow and maximum electrical frequency at 100% skin depth comparable to typical 4/0 AWG round wire. One of ordinary skill in the art will recognize that the cross-sectional area and dimensions of the conducting elements 22 may be selected as a function of the desired electrical characteristics in addition to other characteristics that may include strength, flexibility and the ability of the conducting elements to conform to a desired profile. Variations in the cross-sectional profile of the conducting elements are not critical to the quality and strength of the magnetic field produced by the coil, as long as the conducting elements remain essentially saturated with electrical current during generation of the magnetic field for magnetic particle testing. The magnetic field (amount of magnetic flux) induced by electric current flowing through the electric coil is normally directly proportional to the current flowing through the wrappings of the coil. When an increase in current flowing through the coil no longer results in an increase in the magnetic flux, the level of current in the coil is said to be the saturation current.

The various disclosed embodiments of this disclosure configure each of a plurality of sections 12 of the electric coil 20 that may be interconnected in a telescoping arrangement such that the current density throughout each of the plurality of sections 12 is approximately the same, thereby resulting in a substantially constant current density through the entire length of the multi-wrap electric coil 20 and the current flowing through all sections 12 of the coil being saturated. Each of the plurality of telescopically interconnected sections 12 may include one length of conducting element 22 and a connector element 24 configured to slidably mate with another length of conducting element 22. The conducting elements 22 and connector elements 24 are selected to maintain a nearly constant current density around the entire circumference of the electric coil, and therefore essentially complete current saturation throughout the entire length of coil during use for magnetic particle inspection. As will be apparent from reading the following description, the terminology “conducting element” refers to the elongated, flat sections extending between each connector element 24. In the exemplary embodiments illustrated in the figures, the conducting elements 22 are elongated flat plate strips with rectangular cross sections and with a thickness approximately equal to the thickness of the peripheral wall of the connector elements 24. The connector elements 24 are formed as flattened loops at the ends of each conducting element 22. Each connector element 24 is also manufactured from a conducting material, and therefore is also actually a “conducting element”. Therefore the distinction between the disclosed “conducting elements” 22 and the disclosed “connector elements” 24 is structural, as shown in the figures, and the terminology does not mean that the connector elements 24 are not also electrically conductive. Although the illustrated embodiments show conducting elements that are elongated flat strips of conducting material, and connector elements formed at an end of each of the conducting elements, alternatives and variations of the disclosed electric coil may include conducting elements that are curved tubes of electrically conductive material and connector elements that may be electrically conductive as well, and that support and guide the tubes of adjacent sections into or along the outside of the tubular conducting element of the adjacent section. Each of the telescopically interconnected sections is configured such that the cross-sectional electric current path around all of the wraps of the electric coil remains saturated with current as the electric coil is expanded or contracted in diameter and circumference, and therefore continues to produce the desired magnetic field in a part positioned within the center opening through the coil.

Changes in the total length of the conducting path in the electric coil 20 will change electrical characteristics of the electric coil, such as the amount of back voltage created by induction as current flows through the coil, and increased electrical resistance as the total length of the conductive path in the electric coil 20 is increased. Back voltage created in the wraps of the electric coil can result in a reduction in the strength of the magnetic field created by current flowing through the electric coil. Various embodiments of the adjustable electric coil 20 according to this disclosure change the total length of the electrical conducting path around the electric coil 20 as the coil is expanded to a larger diameter and circumference, or contracted to a smaller diameter and circumference. In embodiments of the electric coil with multiple telescopically interconnected sections 12, which each include a separate conducting element 22 and connector element 24, the adjustable electric coil 20 may also be used in conjunction with a voltage regulator. The voltage regulator may adjust the voltage driving the current through the coil either automatically or manually as the coil is expanded and contracted. In other alternative embodiments (not illustrated), the total length of the conductive path in the electric coil may remain the same as the diameter and circumference of the adjustable coil is expanded and contracted. These alternative embodiments may include a single long length of conducting element that is configured into the multiple wraps of the electric coil, with one end of the conducting element being collected on some type of reel mechanism that takes up the extra length of conducting element as the coil is reduced in diameter and circumference, and lets out additional length of conducting element as the coil is expanded. The voltage and current applied to the coil would flow through the entire length of conducting element, including the length taken up and let out by the reel mechanism as the coil is contracted and expanded. Therefore, the length of the conducting path would not change significantly during adjustment of the diameter and circumference of the coil. In this type of arrangement, the coil could be adjusted in diameter and circumference without any significant change in back voltage or resistance of the coil, and therefore without any need to automatically or manually adjust the voltage applied to the coil. Materials from which the conducting elements may be formed include copper and other metals with good electrical conductivity.

Each of the wraps of the electric coil 20 may be positioned laterally next to each other and configured to have approximately the same circumference and diameter, such that the total width of the coil is determined by the number of wraps. The arrangement of the wraps of the coil laterally next to each other results in an additive effect for the magnetic field produced by current flowing through the wraps. The adjustable electric coil 20 may be mounted on a magnetic particle testing bench, typically positioned with the individual wraps of the coil 20 oriented in substantially parallel planes that are perpendicular to an axis extending between a headstock and a tailstock on a bed of the testing bench. The central opening through the coil may be aligned with the axis between the headstock and the tailstock such that a part to be inspected may be mounted on the bench in between the headstock and tailstock and extending through the center of the coil. The coil and/or the part being inspected may be moved relative to each other on the bench as the voltage and current applied to the coil generates a magnetic field that includes lines of magnetic flux penetrating through the part being tested. Defects and anomalies in the part result in changes to the direction of some of the magnetic flux lines. Solutions, powders, or mixtures containing magnetic particles may be applied to the surface of the part as the part is positioned and/or moved relative to the coil. The magnetic particles will orient themselves with the lines of magnetic flux in the part, thereby revealing any such defects and anomalies to the naked eye.

The adjustable feature of the magnetic coil according to this disclosure facilitates adjustment of the circumference of the coil and the inner diameter of the opening through the coil while the coil is mounted on the bench. As a result, a large number of different sized parts may be tested on the same magnetic particle test bench by simply adjusting the diameter of the electric coil in place on the testing bench to match the inner diameter of the coil to the outer diameter of the part being tested, and obtain the best possible fill factor between the coil and the part being tested. This adjustable feature increases the adaptability and flexibility of the magnetic particle inspection process and the electric coil according to various aspects of this disclosure without the need for a number of different specialty coils having different diameters in order to accommodate different parts or parts with several different outer diameters. A close fit between the inner diameter of the coil 20 and the part being tested or the portion of a part being tested (referred to as the best “fill factor”) provides a better coupling of the magnetic field to the part being tested.

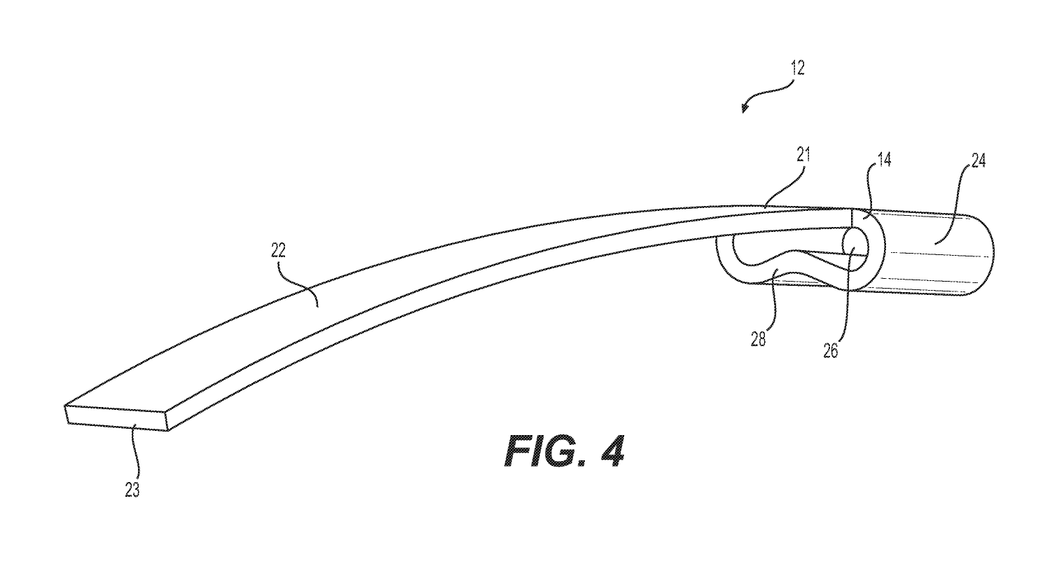

An electric coil 20 according to various exemplary embodiments of this disclosure may be formed from a plurality of separate sections 12 that each include a length of the conducting element 22 and a connector element 24. In some embodiments, each of the separate conducting elements 22 may be joined at a proximal end 21 with one end surface 14 of a peripheral wall of the connector element 24, as shown in FIG. 4. The end surfaces 14 of each connector element 24 are on opposite ends of each connector element 24 in a direction substantially parallel to the outer circumference of the electric coil. Each conducting element 22 intersects with the one end surface 14 of the connector element 24 at approximately a 90 degree angle. The terminology “substantially parallel” and “at approximately a 90 degree angle” refers to within reasonable manufacturing and/or assembly tolerances.

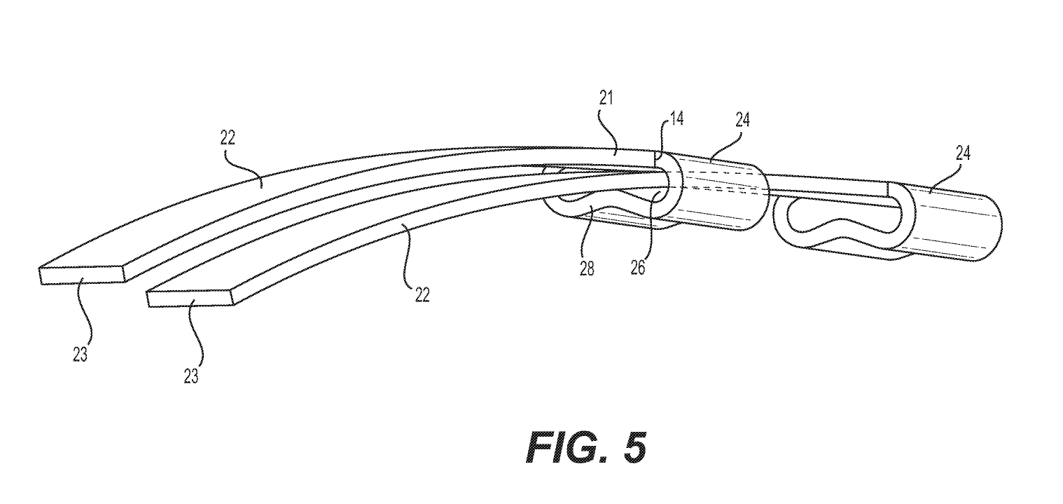

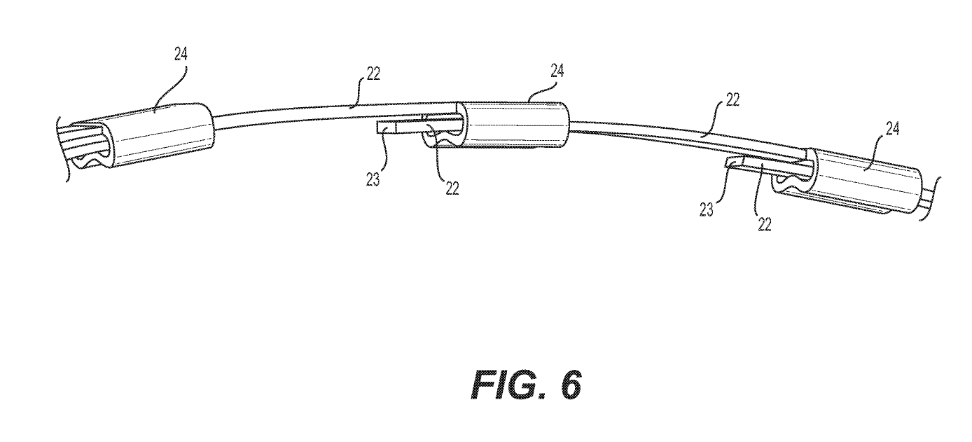

Each connector element 24 may be formed as a crimped connector with a cross-sectional profile that includes a central opening 26 defined by the peripheral wall of the connector element. A convex portion 28 along a bottom portion of the peripheral wall of the connector element may be configured to jut into the central opening 26 and provide a sliding contact with a conducting element 22 of an adjacent section that is passed through the central opening 26. The convex portion 28 is a portion of the peripheral wall that is deformed inwardly into the central opening 26 so as to contact the conducting element 22 from an adjacent section inserted through the central opening 26. The convex portion 28 provides a sliding fit with the conducting element 22 and ensures good, continuous electrical contact between the conducting element 22 of one section 12 and the connector element 24 of the adjacent section 12 as the two adjacent sections 12 are moved apart and together to change the diameter and circumference of the electric coil 20. The sections 12 are configured such that movement of two adjacent sections 12 a greater or lesser distance from each other results in the conducting element 22 of one section 12 being inserted a lesser or greater distance, respectively, through the central opening 26 of the connector element 24 of the adjacent section 12. As shown by a comparison of the exemplary two sections 12 of an electric coil 20 illustrated in FIGS. 5 and 6, as the conducting element 22 of one section 12 is inserted farther through the central opening 26 in the connector element 24 of an adjacent section 12, the overall diameter and circumference of the coil 20 will be reduced. FIG. 5 illustrates the distal end 23 of the conducting element 22 of a first section 12 on the right inserted far enough to the left through the central opening 26 in the connector element 24 of a second adjacent section 12 such that the right hand connector element is closer to the left hand connector element than in the expanded arrangement of FIG. 6. The contracted configuration of FIG. 5 results in a greater amount of overlap between the conducting elements 22 of two adjacent sections 12 than the expanded configuration of FIG. 6.

As shown in the exemplary embodiment of FIGS. 5 and 6, each conducting element 22 may be joined at a proximal end 21 to the end surface 14 of the peripheral wall of the connector element 24, on one side of the central opening 26 through the connector element 24. The joint between the conducting element 22 and the connector element 24 may be formed by known joining processes, including welding, brazing, etc. Variations of the disclosed sections 12 may include forming each of the conducting elements 22 integrally with an associated connector 24. In this variation, each section 12 may be formed by stamping or otherwise forming the entire section 12 from a single piece of conductive material to form an elongated conducting element 22 together with laterally extending tabs at a proximal end of the conducting element that may then be deformed by bending the tabs into the oblong enclosed loop of the connector element 24. In this configuration the laterally extending tabs form the peripheral wall of the connector element 24. The ends of the laterally extending tabs may be bent down and together or up and together relative to the elongated conducting element 22, and then touched and/or joined together to form the convex portion 28 of the peripheral wall of the connector element 24. The convex portion 28 of the peripheral wall of each connector element 24 may be formed to provide a tight fit with the conducting element 22 from an adjacent section.

Still further variations to the process for forming the sections with conducting element 22 and connector element 24 may include forming the connector element 24 by deforming a round section of conducting material into the oblong, flattened loop configuration shown in the figures. After formation of the connector elements 24, the conducting elements 22 may be joined to each connector element, extending from one end face of the peripheral wall of each connector element 24. In some variations, the convex portion 28 may also include an additional lip formed after insertion of the conducting element 22 from an adjacent section, and/or another lip or protrusion may be formed on the distal end 23 of the conducting element 22 such that the lip(s) will prevent two adjacent sections from being disconnected when the sections are moved apart to increase the diameter and circumference of the coil 20. Assembly of the plurality of sections into an electric coil may also include laying the conducting element 22 of a first section at least partially over the laterally extending tabs at the proximal end of the conducting element of an adjacent second section before bending the ends of the laterally extending tabs of the second section around the conducting element 22 of the first section and crimping the ends together to form the connector element 24 slidably engaged with the conducting element 22.

Magnetic particle inspection (MPI) processes are non-destructive methods for the detection of surface and sub-surface indications in ferromagnetic materials. These MPI processes make use of an externally applied magnetic field generated by the electric current sent through the electric coil 20 to produce a magnetic field through the material of a part being tested. The presence of a surface or near surface defect or anomaly in the material of the part being tested causes distortion in the magnetic flux through the indication, which in turn causes surface detectable leakage of the magnetic fields at the indication. Magnetic particles are applied to the magnetized article and are attracted by the surface field in the area of the indication. The magnetic particles may be applied across the part by air or another fluid. Any defect or anomaly causes the lines of magnetic flux to leave the part, creating two new magnetic poles that attract the particles. The accumulation of these magnetic particles indicates the presence of a defect or anomaly. Magnetic particles may be finely divided iron, magnetic iron oxide, magnetite or other magnetic particles. In one embodiment, the magnetic particles may be between about 2 and about 14 microns. The magnetic particles may be held in suspension in a suitable liquid. In one embodiment, the liquid may be an organic solvent such as oil or kerosene. In another embodiment, the liquid may be water or other inorganic solvent. After the part to be tested is mounted on the bench of a magnetic particle inspection apparatus, the magnetic particles are applied by spraying, painting, brushing or other application technique over the magnetized article. The magnetic particles are attracted by the surface field in the area of an indication to indicate the presence of a defect or anomaly. The magnetic particles may be colored and/or coated with fluorescent dyes that are made visible with a UV light source. The magnetic particles are attracted by the surface field in the area of an indication and hold on to the edges of the indication to reveal it as a build-up of particles. Because indications can present a variable aspect relative to the direction of the applied field, in some applications two orthogonal orientations of the applied magnetic field, chordal and radial, may be implemented to inspect an elongated article such as an engine crankshaft or a turbine or compressor blade. Orienting the part differently as the part is passed through the central opening through the electric coil can produce different magnetic field orientations.

The adjustable coil 20 according to various exemplary embodiments of this disclosure can be expanded to an enlarged diameter and circumference, and contracted to a smaller diameter and circumference by manually moving some or all of the sections apart from each other and together. Two adjacent sections may be moved apart or together by simply moving the connector elements 24 of each section farther apart or closer together. This process could be repeated sequentially around the outer circumference of the electric coil 20 in order to retain a substantially circular central opening through the coil of expanding and contracting diameter. The flat conducting elements 22 may each be formed with a slight curvature along their length so that each conducting element slides more easily through a connector element 24 of an adjacent section when the sections are all joined together into the electric coil. As shown in FIGS. 5 and 6, as the conducting element 22 of a first section is inserted farther through the central opening 26 of the connector element 24 on an adjacent second section, the distal end 23 of the conducting element 22 of the first section is positioned below the conducting element 22 of the second section. The overlapping portions of the conducting elements 22 of two adjacent sections may separate more or less from each other depending on the overall diameter of the electric coil and therefore the curvature of each conducting element 22. Additionally, since the conducting element 22 of each section is joined to the peripheral wall of the connector element 24 on one side of the central opening 26 defined through the connector element 24, inserting the conducting element 22 of one section through the central opening 26 of an adjacent section will result in the conducting element being angled slightly away from the conducting element 22 of the adjacent section.

The electrical current flowing through the electric coil 20 will follow the path of least resistance, and will therefore flow through each connector element 24 and the length of conducting element 22 between each connector element. Therefore, as the connector elements are moved closer together, as shown in FIG. 5, the total length of the conducting path for the electric coil will reduce. As the connector elements are moved farther apart, as shown in FIG. 6, the total length of the conducting path for the electric coil will increase. If desired, a strap-type wrench may be applied around the outer peripheral circumference of the electric coil and tightened to exert radially inward forces equally around the entire outer peripheral surface of the coil. Such a tool may help to ensure a smooth transition from a larger diameter and circumference to a smaller diameter and circumference. An expander tool may also be applied inside the central opening of the coil to exert radially outward forces equally around the entire inner peripheral surface of the coil. As the number of total wraps making up the electric coil are increased, tools such as the strap-type wrench and the expander tool may be useful to ensure that all of the sections for each of the wraps are moved a substantially equal amount relative to each other, and the inner profile of the central opening through the coil remains essentially circular in configuration.

### INDUSTRIAL APPLICABILITY

The disclosed adjustable electric coil may be applicable to any magnetic particle inspection apparatus that includes an electric coil that will accommodate different sized parts or parts with different sized portions. The disclosed adjustable electric coil enables magnetic particle inspection of a variety of different sized parts without requiring the disassembly of the magnetic particle inspection apparatus in between inspecting each of the different sized parts, or different sized portions of a part, and replacement of one electric coil with one or more different specialty electric coils having different diameters and circumferences.

The adjustable electric coil according to various implementations of this disclosure may be assembled from a plurality of separate sections that each include the elongated conducting element 22 joined with the connector element 24. Each elongated conducting element 22 of each section is slidably received through a central opening 26 in a connector element 24 of an adjacent section. Each elongated conducting element 22 may be joined at a proximal end 21 to the end surface 14 of the outer peripheral wall of the connector element 24 of the same section. The intersection between the proximal end 21 of the conducting element and the end surface of the outer peripheral wall of the connector element 24 is positioned on one side of the central opening 26 through the connector element 24. The joint between the conducting element 22 and the connector element 24 may be formed by known joining processes, including welding, brazing, etc.

Instead of joining a separate conducting element to a connector element to form each section of the electric coil, each of the sections may be formed as an integral unit. The conducting elements 22 may be formed integrally with associated connector elements 24, such as by stamping the entire section from a single piece of conductive material. The elongated conducting element 22 may be formed with laterally extending tabs at a proximal end of the conducting element, and the tabs may be bent in a direction perpendicular to a plane of the conducting element to form the oblong enclosed portion of the connector element 24. The convex portion 28 of each connector element 24 may be formed to provide a tight fit with the conducting element 22 from an adjacent section. In some variations, the convex portion 28 and/or the distal end 23 of each conducting element 22 may also include an additional lip or protrusion formed after insertion of the conducting element 22 from an adjacent section, such that the lip or protrusion will prevent two adjacent sections from being disconnected when the sections are moved apart to increase the diameter and circumference of the coil 20.

The disclosed exemplary embodiments of the adjustable electric coil include each of the conducting elements 22 joined along a proximal end 21 to a straight upper portion of the outer peripheral wall of the connector element 22. The lower portion of the outer peripheral wall of the connector element 22 on the opposite side of the central opening 26 through the connector element 22 includes the convex portion 28 configured to slidably engage the distal end portion of a flat conducting element 22 from an adjacent section. One of ordinary skill in the art will recognize that other telescopically interconnecting configurations of adjacent sections of the electric coil are also contemplated by this disclosure. As long as the cross-sectional electric current path around the electric coil results in each telescopically interconnected section having closely matching current densities as current flows through the coil, and the coil remains saturated with current around its periphery, the lines of magnetic flux generated by the coil remain substantially evenly distributed through the part being tested.

It will be apparent to those skilled in the art that various modifications and variations can be made to the adjustable electric coil for performing magnetic particle inspections. Other embodiments will be apparent to those skilled in the art from consideration of the specification and practice of the disclosed adjustable electric coil. It is intended that the specification and examples be considered as exemplary only, with a true scope being indicated by the following claims and their equivalents.

What is claimed is:

1. An adjustable electric coil for magnetic particle inspection, comprising:
a plurality of telescopically interconnected sections;
each of the interconnected sections including a connector element and a conducting element, the conducting element being joined at a proximal end to an end surface of a peripheral wall of the connector element, and a central opening defined through the connector element on one side of the conducting element; and
wherein the conducting element of each section is inserted through the central opening of an adjacent connector element of an adjacent section.

2. The adjustable electric coil of claim 1, wherein the conducting element of each section extends adjacent to and overlaps with at least a portion of the conducting element of the adjacent section.

3. The adjustable electric coil of claim 2, wherein a greater length of the conducting element of each section extends adjacent to and overlapping with the conducting element of the adjacent section when the electric coil is adjusted to a smaller diameter than when the electric coil is adjusted to a larger diameter.

4. The adjustable electric coil of claim 1, wherein the conducting element of at least one of the telescopically interconnected sections is formed integrally with the connector element of the at least one section.

5. The adjustable electric coil of claim 4, wherein each of the telescopically interconnected sections is formed from a single piece of conductive material, and the connector element of each of the sections is formed by tabs extending laterally from a proximal end of the conducting element and bent away from a plane of the conducting element to form the connector element at the proximal end of the conducting element.

6. The adjustable electric coil of claim 1, wherein each connector element includes a convex portion of the peripheral wall extending into the central opening defined through the connector element and slidably engaging the conducting element of an adjacent section.

7. The adjustable electric coil of claim 1, wherein at least three wraps of the coil are formed by the plurality of telescopically interconnected sections, with the wraps of the coil being positioned laterally adjacent to each other such that the width of the electric coil is at least three times the width of each section.

8. The adjustable electric coil of claim 1, wherein at least five wraps of the coil are formed by the plurality of telescopically interconnected sections, with the wraps of the coil being positioned laterally adjacent to each other such that the width of the electric coil is at least five times the width of each section.

9. The adjustable electric coil of claim 1, wherein the connector element of each interconnected section is an oblong flattened loop formed at an end of the conducting element and configured to slidably receive a distal end of a conducting element from an adjacent section.

10. A section for an adjustable electric coil used to perform magnetic particle inspection of a component, the section comprising:
a connector element and a conducting element, the conducting element being joined at a proximal end to an end surface of a peripheral wall of the connector element, and a central opening defined through the connector element on one side of the conducting element; and
wherein the conducting element of each section is configured to be inserted a greater or lesser distance through an opening in an adjacent connector element of an adjacent section configured to be telescopically interconnected with the section.

11. The section of claim 10, wherein the conducting element is configured to extend adjacent to and overlap with at least a portion of a conducting element of an adjacent section when the conducting element of an adjacent section is inserted through the central opening of the connector element to form two telescopically interconnected sections.

12. The section of claim 11, wherein a greater length of the conducting element of the adjacent section extends adjacent to and overlaps with the conducting element when the two telescopically interconnected sections are moved closer together than when the two interconnected sections are moved farther apart.

13. The section of claim 10, wherein the conducting element is formed integrally with the connector element.

14. The section of claim 13, wherein the connector element is formed by tabs extending laterally from a proximal end of the conducting element and bent away from a plane of the conducting element to form the connector element at the proximal end of the conducting element.

15. The section of claim 10, wherein the connector element includes a convex portion of the peripheral wall extending into the central aperture and configured to slidably engage a conducting element of an adjacent section when the section and the adjacent section are telescopically interconnected.

16. The section of claim 10, wherein the connector element is an oblong flattened loop formed at an end of the conducting element and configured to slidably receive a distal end of a conducting element from an adjacent section.

17. A method of forming an adjustable electric coil for use with a magnetic particle inspection apparatus, the method comprising:
forming a plurality of sections configured to be telescopically interconnected with each other;
each of the interconnected sections including a connector element and a conducting element, the conducting element being joined at a proximal end to an end surface of a peripheral wall of the connector element, and a central opening defined through the connector element on one side of the conducting element; and
inserting the conducting element of each section through the central opening of an adjacent connector element of an adjacent section.

18. The method of claim 17, further including inserting the conducting element of each section far enough through the central opening of the adjacent connector element of the adjacent section such that the conducting element extends adjacent to and overlaps with at least a portion of the conducting element of the adjacent section.

19. The method of claim 18, wherein a greater length of the conducting element of each section extends adjacent to and overlapping with the conducting element of the adjacent section when the adjustable electric coil is adjusted to a smaller diameter than when the electric coil is adjusted to a larger diameter.

20. The method of claim 17, further including forming the conducting element of at least one of the sections integrally with the connector element of the at least one section.
